(19) United States
(12) Patent Application Publication
(10) Pub. No.: US 2009/0160493 A1
(43) Pub. Date: Jun. 25, 2009

(54) System and Method for Generating a Spread-Spectrum Clock Signal

(75) Inventors: Zhihong You, Plano, TX (US); Liming Xiu, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/960,840

(22) Filed: Dec. 20, 2007

(51) Int. Cl. H03B 21/00

(52) U.S. Cl. 327/105

(57) ABSTRACT

A circuit for, and method of, generating a spread-spectrum clock signal. In one embodiment, the circuit includes: (a) a modulator configured to generate a modulated control value, and (b) a frequency synthesizer coupled to the modulator and configured to generate a spread-spectrum clock signal based on a variation of the modulated control value, the frequency synthesizer having a directly-derivable frequency response output.

### TECHNICAL FIELD OF THE INVENTION

The invention is directed, in general, to manipulating a frequency spectrum and, more specifically, to manipulating a frequency spectrum of a spread-spectrum clock signal.

### BACKGROUND OF THE INVENTION

Clock signals are playing an increasingly important part of processor and computer system architectures. Whenever a transition within part of the processor and computer system architecture occurs, some electromagnetic energy is radiated. Therefore, generation and distribution of clock signals also generates radiated energy. However, this radiated energy can create problems in the processor and computer system architectures, such as static buildup or high-frequency interference. This is especially a problem at higher clock signal frequencies demanded by today's computer architecture.

Interestingly, clock signals waveforms can be regarded as a superposition of corresponding specific sine waves at various frequencies. The more energy a specific sine wave has, the stronger it is and the larger its amplitude. Unfortunately, the energy carried by a given sine wave can interfere with proper computer system operation, especially if some feature of the processor or computer architecture is particularly vulnerable to a particular radiated sine frequency.

To combat this problem, a changing range of clock signal frequencies can be used in today's processors and computer architecture systems. For instance, a clock signal could have a frequency of 1.01 Gigahertz for a first microsecond, and could have a frequency of 0.99 Gigahertz for a second microsecond, and 1.03 Gigahertz for a third microsecond.

Because the frequency of the clock signals change over time, the frequencies of their corresponding sine waves change over time as well. In other words, sine waves corresponding to changing clock signals are “spread” over a spectrum of sine frequencies (i.e., a “spread spectrum”). The average radiated energy of a given sine frequency can be reduced because this sine frequency may not be used during a given time period. Instead, the energy is radiated at some other sine wave frequency for the given time period.

Traditionally, the spread spectrum clock signal is generated by using phase-locked loop (PLL). Generating a spread spectrum clock signal may be achieved either by applying a signal on a control line of a voltage controlled oscillator (VCO) or by dithering a divider circuit inside the PLL. In these approaches, the resulting spread spectrum can be both inaccurate and hard to control.

### SUMMARY OF THE INVENTION

To address the above-discussed deficiencies of the prior art, the invention provides, in one aspect, a circuit for generating a spread-spectrum clock signal. The circuit comprises (a) a modulator configured to generate a modulated control value and (b) a frequency synthesizer coupled to the modulator and configured to generate a spread-spectrum clock signal based on a variation of the modulated control value, the frequency synthesizer having a directly-derivable frequency response output.

Yet another aspect of the invention provides a system for generating a spread-spectrum clock source. The system comprises: (a) a generator configured to generate a plurality of equidistant phase-shifted clock signals, (b) a modulator configured to generate a modulated control value and (c) a frequency synthesizer coupled to the modulator and configured to generate a spread-spectrum clock signal based on a variation of the modulated control value, the frequency synthesizer having a directly-derivable frequency response output.

Yet another aspect of the invention provides a method of generating a spread spectrum clock signal. The method comprises: selecting a modulation pattern, generating a first modulated control value as a function of the modulation pattern, receiving the first control value into a frequency synthesizer having a directly-derivable frequency response, producing a first clock frequency as a function of the first modulated control value, generating a second modulated control value as a function of the selected modulation pattern, receiving the second modulated control value to the frequency synthesizer having the directly-derivable frequency response, and producing a second clock frequency as a function of the second modulated control value. In at least some embodiments, if the method does not end, a new second modulated control value is selected as a function of the selected modulation pattern.

### BRIEF DESCRIPTION OF THE DRAWINGS

For a more complete understanding of the invention, reference is now made to the following descriptions taken in conjunction with the accompanying drawings, in which:

FIG. 1 illustrates one embodiment of spread-spectrum clock signal generator (“SSCSG”) constructed according to the principles of the invention that employs a modulated control word;

FIG. 2A illustrates one embodiment of a modulator that generates modulated control words constructed according to the principles of the invention for use with an SSCSG;

FIG. 2B illustrates an output of one embodiment of a modulated control word generator for use with an SSCSG constructed according to the principles of the invention;

FIG. 3 illustrates an exemplary frequency transfer function of a SSCSG that includes a frequency synthesizer having a directly-derivable frequency response constructed according to the principles of the invention;

FIG. 4 illustrates that a frequency transfer function, generated by a SSCSG of FIG. 1, that can be improved to a linear function when operating over a small range;

FIGS. 5A-5B illustrate a relationship between a change of a modulated control word that is input into a SSCSG constructed according to the principles of the invention and a change of a clock frequency output of the SSCSG;

FIG. 6 illustrates a spectrum analysis of a spread spectrum clock signal that uses one example of a triangle wave modulation constructed according to the principles of the invention; and

FIGS. 7A and 7B illustrate a flow chart of generating modulated control values for generating a spread spectrum clock signal output from a frequency synthesizer having a directly-derivable frequency response practiced according to the invention.

### DETAILED DESCRIPTION

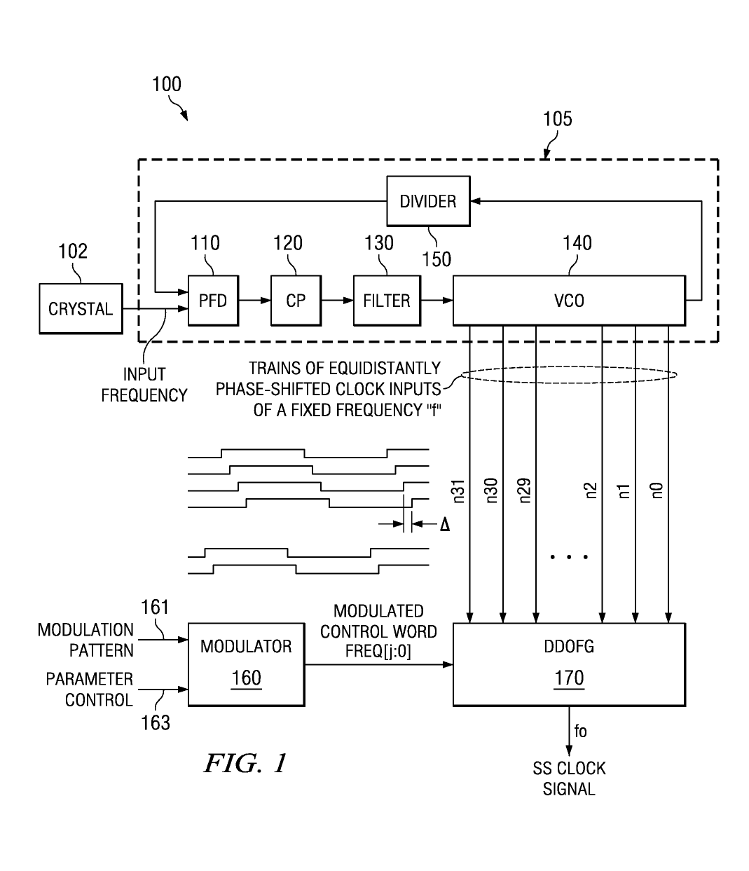

FIG. 1 illustrates an SSCSG 100 constructed according to the principles of the disclosure. Generally, the SSCSG 100 is directed to a generation or a synthesis of spread-spectrum (“SS”) clock signals. The disclosure advantageously recognizes that, in a generation of SS clock signals, it is useful to have a level of controllable correlation when changing from a first SS output clock frequency to a second SS output clock frequency. In the disclosure, “synthesizing” and “generating” are synonymous.

The disclosure further recognizes that, for certain frequency synthesizers, as will be described later, a high degree of control over an SS clock output can indeed be maintained when generating and changing SS clock output signals. In the disclosure, this high level of control can occur through employment of a modulated control value, such as a modulated control word, which is used to control a synthesis of output frequencies by a certain types of frequency synthesizers.

This disclosure still further recognizes that, with employment of a “directly-derivable” output frequency synthesizer in conjunction with the modulated control value, an improved spread spectrum control can result. A “directly-derivable” output frequency generator is generally defined as a frequency generator that generates a frequency response from a given control value, through a precisely, mathematically describable mechanism. One such directly derivable output frequency generator is a “flying adder” frequency synthesizer.

Aspects of the improvement may include, in generating and controlling a spread spectrum clock output, the recognition and employment of: a) a directly-derivable output frequency generator having a correlated directly-derivable, precise output function, b) for small areas of a change of an input value (e.g., “a modulated word”), the change in the output frequencies of the SS output clock signals becomes linear, c) that the frequency synthesizer has an effectively-instantaneous response speed. More specifically, after the moment of control word update, the output frequency will be changed in next clock cycle and, d) the frequency resolution of the SSCGS 100 could be very fine, such as a fraction of a cycle per second. In some embodiments, this resolution is controllable through the number of fractional bits used in the control word used in a directly-derivable output frequency generator.

In some embodiments, the SSCSG 100 includes a crystal 102 coupled to a phased-locked loop (“PLL”) 105. The PLL 105 includes a phase and frequency detector (“PFD”) 110 coupled to a charge pump (“CP”) 120. The CP 120 is coupled to a filter 130. The filter 130 is coupled to a voltage controlled oscillator (VCO) 140. A divider 150 is also coupled between the VCO 140 and the PFD 110. The VCO 140 generates a plurality of trains of equidistantly phase-shifted clock inputs. In the illustrated embodiment, there are 32 separate clock pulse trains, n₀-n₃₁, each clock pulse train phase shifted by 2π/32 radians, although in other embodiments, there are other numbers of separate clock pulse trains.

The PLL 105 is also coupled to a “directly-derivable” output frequency generator (“DDOFG”) 170, such as a flying-adder frequency synthesizer (“FAFS”) constructed according to the principles of the invention, although other directly-derivable output frequency generators are within the scope of the disclosure. U.S. Pat. No. 6,329,850 to Mair, et al., entitled “Precision Frequency and Phase Synthesis,” U.S. Pat. No. 6,940,397 to Xiu, et al., entitled “Scalable High-Speed Precision Frequency and Phase Synthesis,” and “A Flying-Adder′ Architecture of Frequency and Phase Synthesis with Scalability” by Xiu, et al., I.E.E.E. Transactions on Very Large Scale Integration Systems, Vol. 10, No. 5, October 2002, pages 637-649, all incorporated herein by reference, contain more information on FAFS.

A modulator 160 is also coupled to the DDOFG 170. The modulator 160 generates the modulated control value, such as a modulated control word. As will be described below, the modulator 160 generates the modulated control word, which is derived from a modulation pattern input 161 and a parameter control 163. This modulated control word varies, at least in part, as a function of time.

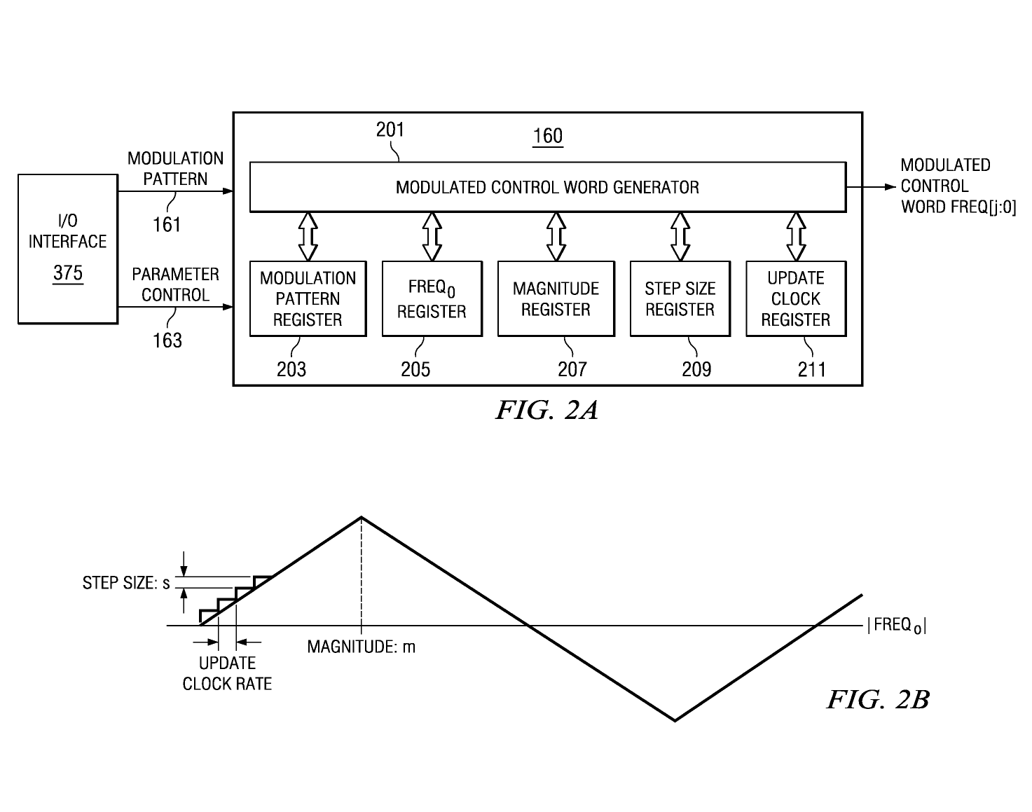

In some embodiments, the modulation pattern is selected from a group including at least one of: a random number modulation pattern, a triangular wave modulation pattern, a saw-tooth wave modulation pattern, and a sigma delta modulation pattern, as will be described below when discussing FIGS. 2A-2B.

The DDOFG 170, as a function of the modulated control word, using the clock input trains n₁-n₃₂ to generate a spread spectrum (“SS”) clock signal (i.e., a first SS clock signal) with the corresponding frequency of the first control word. After a given amount of time or system cycles as controlled by an update clock signal, a second modulated control word is inputted to the DDOFG 170 and the SS clock signal's frequency is updated, (i.e., a second SS clock signal) which corresponds to this second control word.

The selection of the second control word alters the frequency components of the SS clock signal, which spreads the spectrum of the clock signal. This change from the first SS clock signal frequency to the second SS clock signal frequency is generally correlated to a change from the first modulated control word to the second modulated control word being employed by the DDOFG 170, such as described above.

Advantageously, in at least some embodiments, through use of the modulated control word, a control of the change of the SS clock signal occurs when employing the directly-derivable frequency generator, such as the DDOFG 170, although other directly-derivable frequency generators are within the scope of the disclosure. Use of a directly-derivable frequency generator with a modulated control value allows a directly-derivable relationship to occur between a change of the modulated control value and a change of a first to a second SS clock signal. In some embodiments, the directly-derivable frequency response relationship is a linear relationship between a change in the modulated control word and a change in the SS clock signal output.

When a control value, such as a control word, is used with a frequency synthesizer that has a directly-derivable frequency response, such as the SSCSG 100, an output clock signal results with a frequency corresponding to the control word. Advantageously, when the control words of the frequency synthesizer are updated in a selected pattern, the output frequency will follow in mathematically predictable fashion as a function of the selected pattern. In some cases, the output frequency will follow in a linear fashion.

FIGS. 2A and 2B illustrate aspects of the modulator 160. The modulator 160 is coupled to an input/output (I/O) interface 375 that generates the modulation pattern 161 and the parameter control 163. The modulator 160 includes a modulated control word generator 201, and is coupled to a modulation pattern register 203, a frequency register 205, a magnitude register 207, a step size register 209, and an update clock register 211. The modulated control word generator generates a modulated control value, such as the modulated control word generated in FIG. 1, through use of values stored in these registers.

In some embodiments, the parameter control 163 includes data selected from a group including at least one of: a magnitude of variation of a control word, a step size of a variation of a control word, an update rate for updating the control word, and an unmodulated frequency control word, as will be discussed below.

As is illustrated in FIG. 2B, the modulation pattern register 203 stores indicia defining the modulation pattern, which shows the pattern of change of the modulated control word. In the illustrated example, the modulation pattern is triangular.

The frequency pattern stored in the frequency register 205 denotes the value about which the modulated control word periodically changes. For instance, the FREQ0 could be set at [1000:0000], which would be the median value of the modulated control word. Alternatively, the FREQ0 value could be set at [1011:1111], depending upon circumstances.

The magnitude register 207 stores the magnitude of the change of the modulated control word. In other words, this sets the limits of the change of the modulation of the control word. In some embodiments, this would be 1% of FREQO, 2% of FREQO, 5%, and so on.

The step size register 209 denotes the amount of change between modulated control word values generated by the modulated control word generator 201. These can be various levels of gradations. The update clock register 211 then is used by the modulated control word generator 201 to select a new modulated value after a certain time period has elapsed. Please note that the DDOFG 170 may, in some embodiments, have a cycle time that is significantly faster than the time referenced in the update clock register 211.

These values are then used by the modulated control word generator 201 to change the value of the modulated control word. The modulated control word is then conveyed to the DDOFG 170 of FIG. 1.

Employment of a modulated control word gives more control over the output of a frequency synthesizer than found in conventional clock generator systems. This control is expressed as a directly-derivable output frequency response. The spread-spectrum clock frequency is a function of the equidistant phase-shifted clock signals and a variation of the varying control value.

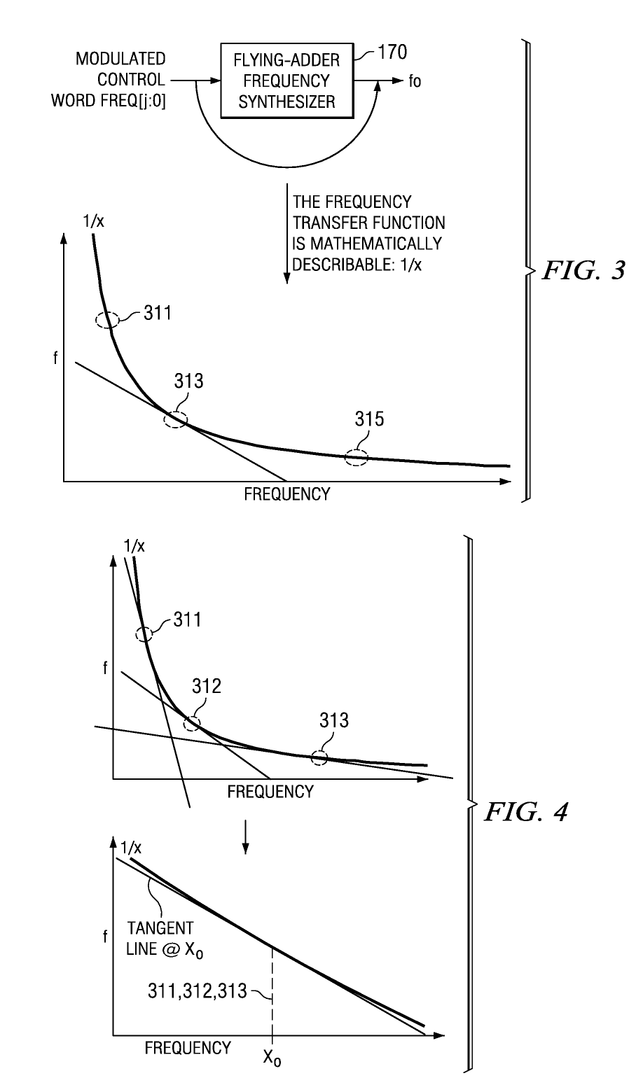

FIG. 3 illustrates more fully that, a rate of change of an output frequency of a DDOFG 170, such as a flying-adder frequency synthesizer, is describable as “1/X,” “X” representing the value of the modulated control word, and therefore the output frequency changes in inverse relationship to the change of the value of the modulated control word. This is unlike conventional systems, wherein there was no directly-derivable control over a change in frequency of an output based on a change of input to a frequency synthesizer. Instead any control over the change of the output frequency was determined on an experimental, ad hoc basis. The disclosure recognizes advantages of using linearity response to improve a spreading of signals to more precisely simulate a random distribution of signals.

The three distinct areas 311, 313, and 315 of FIG. 3 all illustrate the SSCGS 100 has a predicable, mathematically describable transfer function: 1/X, i.e., an “inverse” relationship. This predictable, mathematically describable transfer function is an improvement over conventional synthesizer frequency control, wherein there was not a directly-derivable mathematical relationship between a change of an input value to generate a SS clock signal, and a change in an output control. In other words, a change of delta in the input value results in a constant times delta in a change of the SS clock signal.

FIG. 4 illustrates that, in further embodiments, when the modulated word varies by a sufficiently small amount, the frequency response of the DDOFG can be improved to substantially linear. This is a further improvement over conventional frequency synthesis technologies.

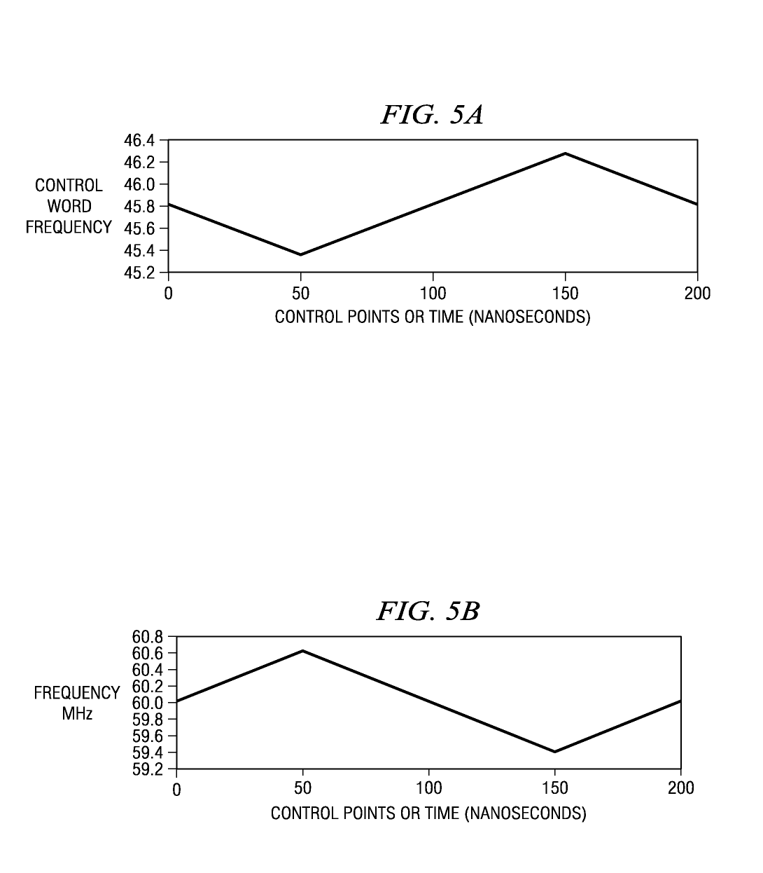

FIGS. 5A and 5B illustrate an inverse relationship between a change in a modulated control word and the change in an output clock frequency of a SSCGS, such as the SSGCS 100. The change of the output frequency of FIG. 5B is a result of a constant change of selection of a value of the modulated control word. These figures demonstrate that, when the modulated control word varies in small range, the output clock frequency follows a change in the modulated control word in a linear fashion.

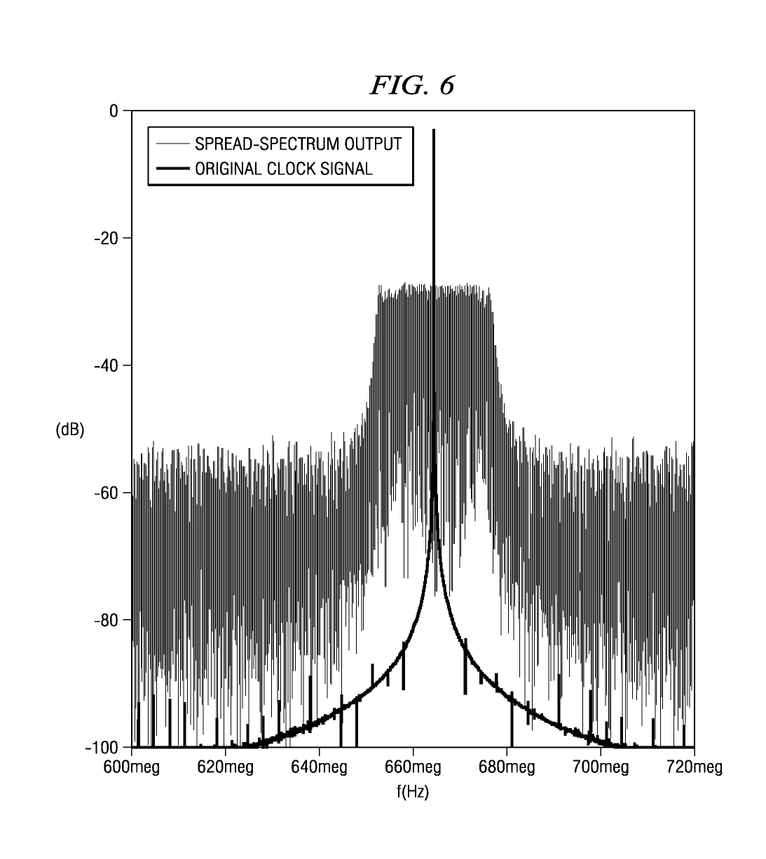

FIG. 6 illustrates a frequency spectral analysis of a modulation pattern of FIG. 2B when using an exemplary triangle wave pattern. Generally, in the SSGCS 100, a center value FREQ0 is selected, then a small variation is added, in a selected pattern to the FREQ0 and this creates a spread spectrum, which spreads the energy of the non-spread clock signal over a specified range.

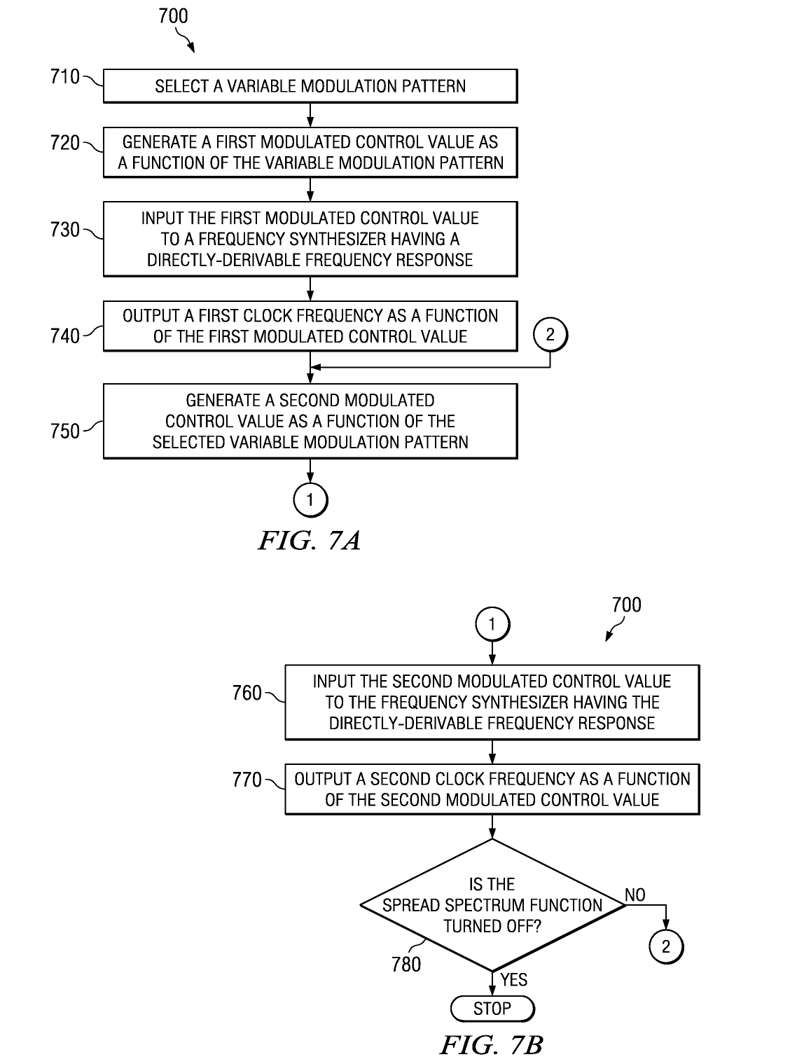

FIG. 7 illustrates a method 700 for generating a spread spectrum signal. In step 710, a modulation pattern is selected. In some embodiments, these modulation patterns can be a random number modulation pattern, a triangular wave modulation pattern, a sawtooth wave modulation pattern, and a sigma delta modulation pattern.

In step 720, a first modulated control value, such as a modulated control word, is generated as a function of the modulation pattern.

In a step 730, a first modulated control value is inputted into a frequency synthesizer. The frequency synthesizer has a directly-derivable output frequency response. In one embodiment, the frequency synthesizer is a FAFS. In step 740, a first clock frequency is outputted as a function of the first control value.

In a step 750, a second modulated control value is generated as a function of the selected variable modulation pattern. In a step 760, the second control value is input into a frequency synthesizer.

In a step 770, a second clock frequency is output as a function of the second control value.

In a step 780, it is determined whether the spread spectrum function of the SSGCS 100 is turned off. In some embodiments, this determination can be derived from contents of the update clock register 211. If it is finished, the method 700 ends. If the method does not end, a new second modulated value is selected in the step 750.

In some embodiments of method 700, if a change of a first control value to a second control value is a value of delta, a variation of output clock frequency between the first output clock frequency and the second output clock frequency is proportional to delta (by a constant value).

Those skilled in the art to which the invention relates will appreciate that other and further additions, deletions, substitutions and modifications may be made to the described embodiments without departing from the scope of the invention.

What is claimed is:

1. A circuit for generating a spread-spectrum clock signal, comprising:
a modulator configured to generate a modulated control value; and
a frequency synthesizer coupled to the modulator and configured to generate a spread-spectrum clock signal based on a variation of the modulated control value, the frequency synthesizer having a directly-derivable frequency response output.

2. The circuit of claim 1 wherein the modulator is configured to employ a modulation pattern and a parameter control.

3. The system of claim 2 wherein the modulation pattern is selected from a group including at least one of:
a random number modulation pattern,
a triangular wave modulation pattern,
a sawtooth wave modulation pattern, and
a sigma delta modulation pattern.

4. The system of claim 2 wherein the parameter control is selected from a group including at least one of:
a magnitude of variation of a clock frequency,
a step size of a variation of a clock frequency, and
an update rate frequency for updating the modulated control value.

5. The system of claim 1 wherein the modulated control value is a modulated control word.

6. The system of claim 1 wherein the frequency synthesizer includes a flying-adder frequency synthesizer.

7. The system of claim 1 wherein the modulated control value has an integer part and a fractional part.

8. The system of claim 1 wherein the frequency synthesizer has a plurality of equidistant phase-shifted clock signals input therein, employable to help generate spread spectrum clock frequencies.

9. The system of claim 1 wherein the directly-derivable frequency response is a linear response of a variation of the modulated control value.

10. A system for generating a spread-spectrum clock source, comprising:
a generator configured to generate a plurality of equidistant phase-shifted input clock signals;
a modulator configured to generate a modulated control value; and
a flying-adder frequency synthesizer having a directly-derivable frequency response output, coupled to receive a change of the modulated control value and further coupled to receive the equidistant phase-shifted input clock signals, the spread-spectrum clock frequency being a function of the plurality of equidistant phase-shifted input clock signals and a variation of the modulated control value.

11. The system of claim 10 wherein the equidistant phase-shifted input clock signals comprise thirty-two phase-shifted input clock signals.

12. The system of claim 10 wherein the directly-derivable frequency response is a linear response of a variation of the modulated control value.

13. The system of claim 10 wherein a plurality of modulated control values correlate to a triangle wave.

14. The system of claim 10 wherein the modulated control value is a modulated control word.

15. The system of claim 10 wherein said generator comprises a phased-lock loop.

16. A method of generating a spread spectrum clock signal, comprising:
selecting a modulation pattern;
generating a first modulated control value as a function of the modulation pattern;
receiving the first modulated control value to a frequency synthesizer having a directly-derivable frequency response;
producing a first clock frequency as a function of the first modulated control value;
generating a second modulated control value as a function of the selected modulation pattern;
receiving the second modulated control value to the frequency synthesizer having the directly-derivable frequency response; and
producing a second clock frequency as a function of the second modulated control value.

17. The method of claim 16 wherein if a change of a first modulated control value to a second value is a value of delta, a variation of clock frequency between the first clock frequency and the second clock frequency is proportional to delta.

18. The method of claim 16 wherein the modulated control value is a modulated control word.

19. The method of claim 16 wherein the modulated control value has an integer part and a fractional part.

20. The method of claim 16 wherein the modulation pattern is selected from a group including at least one of:
a random number modulation pattern;
a triangular wave modulation pattern;
a sawtooth wave modulation pattern; and
a sigma delta modulation pattern.

21. The method of claim 16 wherein the frequency synthesizer having a directly-derivable frequency response is a flying adder frequency synthesizer.

22. The method of claim 16, further comprising selecting a new second modulated control value if an update clock signal is not finished.
